(19) United States
(12) Patent Application Publication
(10) Pub. No.: US 2026/0169383 A1
(43) Pub. Date: Jun. 18, 2026

(54) INK-JET RECORDING HEAD AND METHOD FOR MANUFACTURING INK-JET RECORDING HEAD

(71) Applicant: CANON KABUSHIKI KAISHA, Tokyo (JP)

(72) Inventors: YOHEI HAMADE, Tokyo (JP); SATOSHI TSUTSUI, Kanagawa (JP); HARUKA YAMAJI, Tokyo (JP); ERIKA KOBATAKE, Kanagawa (JP)

(21) Appl. No.: 19/386,417

(22) Filed: Nov. 12, 2025

(30) Foreign Application Priority Data
Dec. 17, 2024 (JP) 2024-220982

(51) Int. Cl. G03F 7/038; B41J 2/16; G03F 7/004; G03F 7/028; G03F 7/095

(52) U.S. Cl. CPC G03F 7/0388; B41J 2/1626; B41J 2/1631; G03F 7/0046; G03F 7/028; G03F 7/0385; G03F 7/095

(57) ABSTRACT

An ink-jet recording head including: a substrate; an ejection port forming member provided on the substrate; and a water-repellent layer provided on the ejection port forming member, wherein the water-repellent layer includes a cured product (A) of a photosensitive resin composition, the photosensitive resin composition includes: a (meth)acrylate (a) having a perfluoropolyether group; a (meth)acrylate (b) having an epoxy group; a multifunctional (meth)acrylate (c); a thermal radical polymerization initiator (d); and a photo cationic polymerization initiator (e), the (meth)acrylate (a) is a (meth)acrylate having a tri- or more functional (meth)acrylic group, and the multifunctional (meth)acrylate (c) is a (meth)acrylate having a weight average molecular weight of not more than 5000 and having a hexa- or more functional (meth)acrylic group.

### BACKGROUND

### Field of the Technology

The present disclosure relates to an ink-jet recording head and a method for manufacturing an ink-jet recording head.

### Description of the Related Art

In recent years, technical development for further improving recording characteristics of ink-jet recording systems has been continued. In an ink-jet recording head, in order to stably eject small liquid droplets, the surface of an opening of an ejection port is often subjected to surface treatment to apply a water-repellent layer thereon. In addition, residual ink on an opening surface of an ejection port is wiped off using a rubber blade or the like to regularly maintain the state of the opening surface of the ejection port. It is required that the water-repellent layer is not eroded by liquid such as ink and remains to adhere to the surface of the opening of the ejection port even when being wiped (rubbed) with a blade or the like. Further, from the viewpoint of simplifying the manufacturing process and reducing the cost, it is desired to form the ejection port and the water-repellent layer together at the same time.

Japanese Patent Laid-open No. 2015-205490, for example, discloses a material that is used for water-repellent and ink-repellent surface treatment and that can be applied on an ejection port forming member and has durability. Japanese Patent Laid-open No. 2015-205490 discloses a composition containing a fluorine-containing epoxy resin obtained by polymerizing a perfluoropolyether group-containing (meth)acrylic monomer having 9 or more carbon atoms and an epoxy group-containing (meth)acrylic monomer.

### SUMMARY

However, in recent years, various inks are used. In addition, it was found that when high-density ink, which is easy to fix, is used, or when durability against rubbing is required, the water-repellent layer formed with the composition disclosed in Japanese Patent Laid-open No. 2015-205490 causes a problem of being unable to always maintain the water-repellent layer on the head surface.

As a result of diligent studies on the above-mentioned problem, the inventors have found that the problem can be solved by appropriately controlling the molecular weight and the number of functional groups of (meth)acrylates in a composition and increasing the crosslinking ability of the (meth)acrylic skeleton moiety, thereby improving the durability.

One embodiment of the present disclosure provides an ink-jet recording head having high water repellency and durability.

Another embodiment of the present disclosure provides a method for manufacturing an ink-jet recording head having high water repellency and durability.

The present disclosure relates to an ink-jet recording head comprising: a substrate; an ejection port forming member provided on the substrate; and a water-repellent layer provided on the ejection port forming member, wherein the water-repellent layer comprises a cured product (A) of a photosensitive resin composition, the photosensitive resin composition comprises: a (meth)acrylate (a) having a perfluoropolyether group; a (meth)acrylate (b) having an epoxy group; a multifunctional (meth)acrylate (c); a thermal radical polymerization initiator (d); and a photo cationic polymerization initiator (e), the (meth)acrylate (a) is a (meth)acrylate having a tri- or more functional (meth)acrylic group, and the multifunctional (meth)acrylate (c) is a (meth)acrylate having a weight average molecular weight of not more than 5000 and having a hexa- or more functional (meth)acrylic group.

Features of the present disclosure will become apparent from the following description of embodiments with reference to the attached drawings. The following description of embodiments is described by way of example.

### BRIEF DESCRIPTION OF THE DRAWINGS

FIG. 1 is a perspective schematic view of an example of the ink-jet recording head.

FIGS. 2A to 2G respectively are a cross-sectional view of an example of the method for manufacturing an ink-jet recording head.

### DESCRIPTION OF THE EMBODIMENTS

In the present disclosure the notations “from XX to YY” and “XX to YY” representing a numerical value range signify, unless otherwise specified, a numerical value range that includes the lower limit and the upper limit of the range, as endpoints. In a case where numerical value ranges are described in stages, the upper limits and the lower limits of the respective numerical value ranges can be combined arbitrarily. In the present disclosure, for instance, a wording such as “at least one selected from the group consisting of XX, YY and ZZ” encompasses XX, YY and ZZ, a combination of XX and YY, a combination of XX and ZZ, a combination of YY and ZZ, and a combination of XX, YY and ZZ.

In the present disclosure, “(meta) acrylic” means “acrylic” and/or “methacrylic.” Similarly, “(meth)acrylate” means “acrylate” and/or “methacrylate.”

The following provides a detailed description of embodiments of the present disclosure. The ink-jet recording head according to the present disclosure is characterized by an ink-jet recording head comprising: a substrate; an ejection port forming member provided on the substrate; and a water-repellent layer provided on the ejection port forming member, wherein the water-repellent layer comprises a cured product (A) of a photosensitive resin composition, the photosensitive resin composition comprises: a (meth)acrylate (a) having a perfluoropolyether group; a (meth)acrylate (b) having an epoxy group; a multifunctional (meth)acrylate (c); a thermal radical polymerization initiator (d); and a photo cationic polymerization initiator (e), the (meth)acrylate (a) is a (meth)acrylate having a tri- or more functional (meth)acrylic group, and the multifunctional (meth)acrylate (c) is a (meth)acrylate having a weight average molecular weight of not more than 5000 and having a hexa- or more functional (meth)acrylic group.

### Composition

The photosensitive resin compositions will be described below.

### (Meth)Acrylate (a) Having a Perfluoropolyether Group

The (meth)acrylate (a) can impart water-repelling performance to the water-repellent layer. The (meth)acrylate (a) is not particularly limited as long as it has a perfluoropolyether group and is a (meth)acrylate having a tri- or more functional (meth)acrylic group. The (meth)acrylate (a) preferably has (meth)acrylate structures at both termini in light of the reactivity with other (meth)acrylates as described below. The phrase “having (meth)acrylate structures at both termini” as used herein means that at least the two terminal groups are (meth)acrylic groups.

The (meth)acrylate (a) having a perfluoropolyether group can exhibit water-repelling performance.

The (meth)acrylate (a) having a tri- or more functional (meth)acrylic group can provide improved crosslinking ability when the photosensitive resin composition is cured, and provide excellent durability of the water-repellent layer. The upper limit is not particularly limited, but from the viewpoint of handling properties, the upper limit is usually hexa-functional or less.

The (meth)acrylate (a) preferably has a tri- to hexa-functional (meth)acrylic group, more preferably a tetra- to hexa-functional (meth)acrylic group and still more preferably a tetra-functional (meth)acrylic group.

Furthermore, because it is easy to design the structure having a large number of (meth)acrylic groups in one molecule, the (meth)acrylate (a) preferably has a urethane bond, and the urethane bond is more preferably linked via an alkyl group to a terminal (meth)acrylic group.

The (meth)acrylate (a) preferably has a weight average molecular weight (Mw) of 5000 or less, more preferably 2500 or less.

When the Mw of the (meth)acrylate (a) is 5000 or less, the (meth)acrylic equivalent is low, and thus the cured product has improved crosslinking ability and the water-repellent layer has excellent durability.

The lower limit of the Mw of the (meth)acrylate (a) is not particularly limited, but is preferably between 1500 to 5000, more preferably 2000 to 4000, and still more preferably 3000 to 4000.

Specifically, the (meth)acrylate (a) is preferably a compound represented by formula (1) below.

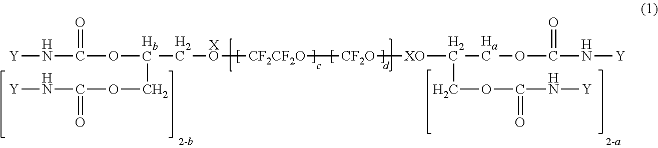

In formula (1), a and b are each independently an integer of 0 to 2 (preferably 1). c is an average number of repetitions of the repeating unit —(CF₂CF₂O)—, d is an average number of repetitions of the repeating unit —(CF₂O)—, c and d each independently represent a number of 0 or more and satisfy 15≤(c+d)≤25. If having both repeating units, these repeating units may be linked via any of block bonds, random bonds, and block bonds and random bonds. Y groups each independently represent a group represented by formula (Y1) or (Y2) below, and X groups each independently represent an alkylene group having 2 or 3 carbon atoms substituted with 1 to 3 fluorine atoms.

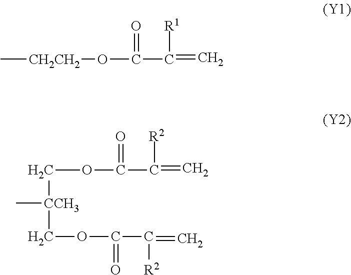

In formula (Y1) and formula (Y2), R¹ and R² each independently, represent a hydrogen atom or a methyl group.

Examples of the compound represented by formula (1) include commercially available products such as AD-1700 (trade name, manufactured by Solvay Specialty Polymers).

One or two or more in combination of the above may be used as the (meth)acrylate (a).

Since many of the (meth)acrylate (b) having an epoxy group and multifunctional (meth)acrylate (c), which will be described later, do not dissolve in a fluorine solvent, an organic solvent is often used in the polymerization reaction. If the (meth)acrylate (a) is soluble in an organic solvent, polymerization can be carried out in the same solvent, and the polymerization reaction tends to proceed easily. It is therefore preferred that the (meth)acrylate (a) is soluble in an organic solvent.

The organic solvent as used herein includes an organic solvent in which the (meth)acrylates (b) and (c) are soluble, and specific examples thereof include at least one selected from the group consisting of ketone group-containing solvents (ketone solvents), ester group-containing solvents (ester solvents), and alcohol group-containing solvents (alcohol solvents), and more specific examples include methyl isobutyl ketone (MIBK). A compound is considered soluble if 1 g or more of the compound can be dissolved in 100 L of a solvent.

The content of the (meth)acrylate (a) in the photosensitive resin composition of the present disclosures is preferably 1 to 60% by mass, more preferably 2 to 40% by mass, and still more preferably 3 to 20% by mass, provided that the total content of all (meth)acrylates in the photosensitive resin composition is 100% by mass.

When the content of the (meth)acrylate (a) is 1% by mass or more, sufficient water repellency and rubbing resistance can be imparted to the water-repellent layer. When the content is 60% by mass or less, the (meth)acrylate is sufficiently compatible with other (meth)acrylates, and the water-repellent layer obtained may have little white turbidity.

### (Meth)Acrylate (b) Having an Epoxy Group

The (meth)acrylate (b) can impart photosensitivity to the water-repellent layer. The (meth)acrylate (b) is not particularly limited as long as the (meth)acrylate has an epoxy group, and it is preferable that the epoxy group is alicyclic or glycidyl in light of the affinity with other (meth)acrylates.

Specifically, the (meth)acrylate (b) is preferably at least one (meth)acrylate selected from the group consisting of glycidyl methacrylate, 3,4-epoxycyclohexylmethyl methacrylate and 4-hydroxybutyl (meth)acrylate glycidyl ether. One or two or more in combination of these (meth)acrylates (b) having epoxy groups may be used.

The content of the (meth)acrylate (b) in the photosensitive resin composition of the present disclosure is preferably 10 to 90% by mass, more preferably 15 to 80% by mass, and still more preferably 30 to 60% by mass, provided that the total content of all (meth)acrylates in the photosensitive resin composition is 100% by mass.

When the content of the (meth)acrylate (b) is 10% by mass or more, the adhesiveness to the underlayer and the durability of the film can be improved. When the content is 90% by mass or less, sufficient water-repellency and curability can be imparted.

### Multifunctional (Meth)acrylate (c)

The (meth)acrylate (c) can increase the reactivity between (meth)acrylates in the photosensitive resin composition.

The (meth)acrylate (c) is not particularly limited as long as the (meth)acrylate (c) has a hexa- or more functional (meth)acrylic group and has a weight average molecular weight of 5000 or less. Because it is easy to design the structure having a large number of (meth)acrylic groups in one molecule and from the viewpoint of the affinity with the (meth)acrylate (a), the (meth)acrylate (c) preferably has a urethane bond, and the urethane bond is preferably linked via an alkyl group to a terminal (meth)acrylic group.

Examples of the (meth)acrylate (c) include commercially available products such as UA-1100H and UA-6LPA manufactured by Shin-Nakamura Chemical Co., Ltd., and Miramer PE210 manufactured by Toyo Chemicals Co., Ltd. One or two or more in combination of the above may be used as the multifunctional (meth)acrylate (c).

The content of the (meth)acrylate (c) in the photosensitive resin composition of the present disclosure is preferably 3 to 60% by mass, more preferably 10 to 55% by mass, and still more preferably 30 to 50% by mass, provided that the total content of all (meth)acrylates in the photosensitive resin composition is 100% by mass.

When the content of the (meth)acrylate (c) is 3% by mass or more, the adhesiveness to the underlayer and the durability of the film can be improved. When the content is 60% by mass or less, sufficient water-repellency can be imparted.

In case where a (meth)acrylate may fall under more than one of (meth)acrylates (a) to (c) of the present disclosure, the (meth)acrylate is regarded as methacrylate (a) when the (meth)acrylate falls under (meth)acrylate (a) even if it can fall under (meth)acrylate (b) or (c), and when the (meth)acrylate does not fall under (meth)acrylate (a) and falls under both (meth)acrylates (b) and (c), the (meth)acrylate is regarded as (meth)acrylate (b) and (meth)acrylate (c).

### Thermal Radical Polymerization Initiator (d)

The thermal radical polymerization initiator (d) is not particularly limited, and preferably has high affinity with the (meth)acrylates (a) to (c). The thermal radical polymerization initiator (d) preferably has a 10-hour half-life temperature of 80° C. or lower. The lower limit of the 10-hour half-life temperature is not particularly limited, and is more preferably 10 to 80° C., and still more preferably 30 to 70° C.

When the thermal radical polymerization initiator (d) has a 10-hour half-life temperature of 80° C. or lower, the reaction between the (meth)acrylates can sufficiently proceed when the water-repellent layer is formed as described later, whereby providing sufficient water-repellency and durability of the film. Examples of thermal radical polymerization initiator having a 10-hour half-life temperature of 80° C. or lower include azobisisobutyronitrile (AIBN), a commercial product V-65 (trade name, manufactured by FUJIFILM Wako Pure Chemical Corp.) and the like.

The content of the thermal radical polymerization initiator (d) in the photosensitive resin composition may be an arbitrary content such that targeted percentages of reaction of the (meth)acrylates can be achieved. From the viewpoint of achieving sufficient percentages of reaction, the content is preferably 0.5 to 10% by mass, and more preferably 0.5 to 5% by mass provided that the total content of all (meth)acrylates in the photosensitive resin composition is 100% by mass.

### Photo Cationic Polymerization Initiator (e)

The photo cationic polymerization initiator (e) is not particularly limited, and is suitably a photo cationic polymerization initiator which does not contain a toxic metal and has high catalytic function allowing curing at a low temperature. Specific photo cationic polymerization initiator selected may be an ionic acid generator.

The cation of the photo cationic polymerization initiator (e) selected is preferably an onium having high absorbability, and more preferably an onium ion such as oxonium, ammonium, phosphonium, sulfonium and iodonium, and among others, still more preferably a sulfonium ion excellent in cationic polymerizability and crosslinking reactivity.

From the viewpoint of cationic photopolymerizability, the photo cationic polymerization initiator (e) preferably has a molar extinction coefficient at a wavelength 365 nm of 0.3 L/(mol cm) or more. The upper limit of the molar extinction coefficient of the photo cationic polymerization initiator (e) is not particularly limited, and is preferably 0.3 to 5.0 L/(mol·cm), and more preferably 1.0 to 3.0 L/(mol·cm).

The molar extinction coefficient is measured according to the following method.

A target compound is dissolved in a solvent with no absorption at a wavelength of 365 nm such as acetonitrile to obtain a solution, the solution is placed in a quartz cell, and the absorbance at a wavelength of 365 nm is measured using a UV-visible/infrared spectrophotometer (manufactured by JASCO Corporation). The molar extinction coefficient can be calculated from the absorbance obtained using the following formula.

$$Molar extinction coefficient = Absorbance / Molar concentration of the compound / Optical path of the cell$$

Specifically, as the photo cationic polymerization initiator (e), for example, at least one compound selected from the group consisting of 4-hydroxyphenyl-methyl-1-naphthylmethylsulfonium, 4-hydroxyphenyl-methyl-benzylsulfonium, 4-hydroxyphenyl-methyl-4-nitrobenzylsulfonium and diphenyl [4-(phenylthio)phenyl]sulfonium may suitably be used.

In order to prevent a film thickness loss of a cured product of the (meth)acrylate (b) in the heating step, it is preferable that there is no residual HF after the exposure/PEB step described later. Specifically, the photo cationic polymerization initiator (e) suitably used has at least one anion selected from the group consisting of tetrakis(pentafluorophenyl)gallate and hexafluoroantimonate.

The content of the photo cationic polymerization initiator (e) in the photosensitive resin composition may be an arbitrary content so as to achieve a targeted sensitivity, and is preferably in the range of 0.00001 to 0.15 times, more preferably 0.00001 to 0.10 times, and still more preferably 0.01 to 0.10 times the mass of the (meth)acrylate (b) having an epoxy group from the viewpoint of achieving a sufficient sensitivity.

### Solvent

The photosensitive resin composition according to the present disclosure may include a solvent as necessary from the viewpoint of applicability. The solvent may be, for example, at least one solvent selected from the group consisting of γ-butyrolactone, ethyl lactate, propylene carbonate, propylene glycol monomethyl ether acetate, methyl isobutyl ketone, butyl acetate, methyl amyl ketone, 2-heptanone, ethyl acetate, methyl ethyl ketone, xylene and alcohols. One or two or more in combination of the above solvents may be used.

### Method for Manufacturing Ink-Jet Recording Head

Next, a method for manufacturing an ink-jet recording head by using the composition described above will be described.

One example of the method of manufacturing the ink-jet recording head according to the present disclosure includes a step of forming a water-repellent layer on a surface of an ejection port forming member of the ink-jet recording head using the photosensitive resin composition according to the present disclosure. The ink-jet recording head manufactured by the method according to the present disclosure has high water repellency and durability.

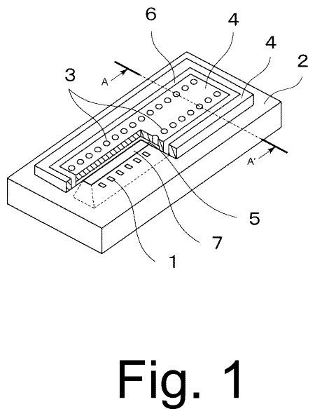

The method for manufacturing the ink-jet recording head is not particularly limited, and examples thereof include the following method. FIG. 1 is a perspective schematic view of the ink-jet recording head according to one embodiment of the present disclosure. The ink-jet recording head has, on an element substrate 2 having a plurality of energy generating elements 1 for ejecting ink, an ejection port forming member 4 provided with an ejection port 3 for ejecting ink, a flow path 5 communicating with the ejection port 3 and holding ink, and a groove 6 formed to reduce an internal stress of the ejection port forming member 4. The substrate 2 is also provided with an ink supply port 7 for supplying ink to the flow path 5.

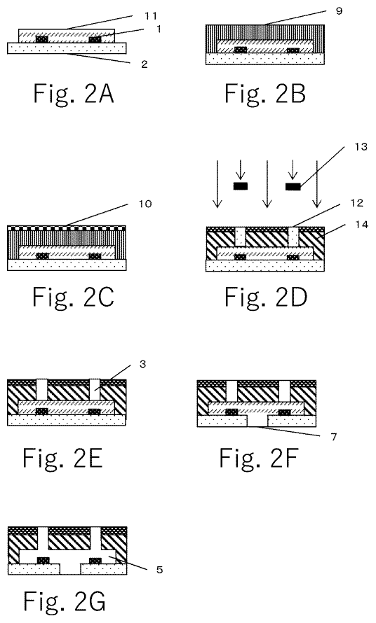

FIGS. 2A to 2G are schematic views showing the A-A′ cross section of the ink-jet recording head illustrated in FIG. 1 in the respective manufacturing steps.

First, on the substrate 2 in which energy generating elements 1 are formed, a positive photosensitive resin layer (not shown) containing a positive photosensitive resin serving as a mold material of the flow path is formed. The positive photosensitive resin is not particularly limited, and is preferably a material having low absorbability of light which is used for exposure of a cationically polymerizable resin layer 9 and a water-repellent layer 10 which are described later in order to prevent deterioration of patterning due to photosensitization during the exposure of the cationically polymerizable resin layer 9 and the water-repellent layer 10. For example, in the case where the light is ultraviolet rays such as i-line, the positive photosensitive resin used may be polymethyl isopropenyl ketone or the like which can be exposed to deep-UV light.

The positive photosensitive resin layer may be formed by, for example, dissolving, as appropriate, the positive photosensitive resin in a solvent, applying the solution by spin coating, and then carrying out pre-baking. The thickness of the positive photosensitive resin layer corresponds to the height of the flow path, and thus is decided, as appropriate, depending on the design of ejection of the ink-jet recording head, and is preferably, for example, 5 to 22 μm.

Next, the positive photosensitive resin layer is patterned to form a mold material 11 (FIG. 2A). The positive photosensitive resin layer may be patterned, for example, by pattern exposure in which the positive photosensitive resin layer is irradiated through a mask with active energy rays that can photosensitize the positive photosensitive resin. Thereafter, the exposed portion of the positive photosensitive resin layer is developed using a solvent or the like that can solubilize the exposed portion, and rinsed to form the mold material 11.

Next, the cationically polymerizable resin layer 9 is formed using a resin composition for an ejection port forming member (FIG. 2B). The resin composition for the ejection port forming member is preferably a composition containing an epoxy resin and a photo cationic polymerization initiator, and the epoxy resin is preferably an alicyclic epoxy resin or a glycidyl epoxy resin. That is, the ejection port forming member is preferably a cured product (B) of a composition containing an epoxy resin and a photo cationic polymerization initiator, and the epoxy resin is preferably an alicyclic or glycidyl epoxy resin.

From the viewpoint of simplifying the manufacturing process and reducing the cost, it is desirable that the water-repellent layer and the ejection port can be formed together by patterning. Because of this, the epoxy resin is preferably an alicyclic epoxy resin or a glycidyl epoxy resin as the water-repellent layer. The photo cationic polymerization initiator may also be the same as the one used for the water-repellent layer.

In the step of forming the cationically polymerizable resin layer 9, for example, the resin composition for the ejection port forming member may be applied to form a coating film. The application method is not particularly limited as long as a uniform film can be formed. For example, spin coating or slit coating can be used.

Next, a water-repellent layer 10 is provided to prevent ink from accumulating in the vicinity of the ejection port (FIG. 2C). In the step of forming the water-repellent layer 10, the photosensitive resin composition according to one embodiment of the present disclosure that forms the water-repellent layer may be applied onto the cationically polymerizable resin layer 9 to form a coating film. For example, spin coating or slit coating can be used. For the purpose of improving the accuracy of the film thickness, the water-repellent layer 10 may be formed by a dry film-making method.

After forming the coating film of the photosensitive resin composition for forming the water-repellent layer, the coating film is baked (heated), thereby allowing polymerization (curing) of the photosensitive resin composition to proceed to form the water-repellent layer 10.

In the step of forming the water-repellent layer 10 where the above baking is regarded as a first heating step, the heating temperature in this step is preferably higher than the 10-hour half-life temperature of the thermal radical polymerization initiator (d) contained in the photosensitive resin composition. More specifically, the heating temperature is preferably 80° C. or higher, and more preferably 90° C. or higher. Because of this, the reaction between the (meth)acrylates in the water-repellent layer can sufficiently proceed, and sufficient water-repellency and durability of the film can be imparted. The heating time is not particularly limited, and is, for example, 1 to 10 minutes.

In general, by baking the composition after application, the water-repellent groups segregate at the air interface, thereby increasing the water repellency. From the viewpoint of simplifying the manufacturing process and reducing the cost, it is preferable to include a step of collectively patterning the resin layer and the water-repellent layer constituting the ejection port forming member after the step of forming the water-repellent layer. In order to allow formation of the ejection port and the water-repellent layer together, it is preferable that the layers are compatible. The step of patterning the resin layer and the water-repellent layer together can be carried out, for example, in exposure and development steps which will be described later.

Next, a step of exposing the cationically polymerizable resin layer 9 is carried out (FIG. 2D). When the cationically polymerizable resin composition is used as described above, a heating (PEB) step as a second heating step may follow the exposure of the resin composition at a wavelength at which photo-curing reaction proceeds. When doing so, in order to further enhance the reactivity of the (meth)acrylate in the water-repellent layer, it is preferable that the heating temperature in the second heating step is higher than that in the first heating step. In FIG. 2D, 14 is the exposed portion and 12 is the non-exposed portion.

That is, it is preferable that the step of forming the water-repellent layer includes the first heating step, the step of patterning includes the patterning exposure step and the second heating step, and the heating temperature during the second heating step is higher than the heating temperature in the first heating step.

Next, the exposed cationically polymerizable resin layer 9 is developed to form a fine pattern (FIG. 2E). Because of this, the ejection port forming member and the flow path forming member can be formed with the same material, and peeling at the interface between the members is less likely to occur. A developer used for the development is suitably a solvent capable of dissolving an uncured epoxy resin. Specifically, an ester solvent or a ketone solvent such as propylene glycol monomethyl ether acetate, methyl ethyl ketone, or methyl isobutyl ketone may be used.

For the purpose of accelerating curing of the resin composition, it is preferable to carry out firing at a temperature higher than the reaction starting temperature of the thermal radical polymerization initiator (d) after the development. Specifically, the firing is preferably carried out at a temperature of 140° C. or higher.

After the firing, the cured product (A) constituting the water-repellent layer preferably has a total percentage of reaction of epoxy groups based on the total epoxy groups in the photosensitive resin composition forming the water-repellent layer of 90% or more and more preferably 95% or more. In addition, in the cured product (A), the total percentage of reaction of (meth)acrylic group based on the total of all (meth)acrylic groups of the (meth)acrylates (a) to (c) is preferably 90% or more, and more preferably 95% or more.

The cured product (A) preferably has a pencil hardness of 3H or more and more preferably 4H or more.

By satisfying the above, sufficient durability can be imparted.

The percentages of reaction of epoxy group and (meth)acrylic group and the pencil hardness can be increased, for example, by increasing the amount of the photo cationic polymerization initiator (e) in the photosensitive resin composition or by increasing the temperatures of the first and second heating steps.

Similarly, after the firing, the cured product (B) of the composition constituting the ejection port forming member has a percentage of reaction of the total epoxy groups based on the total epoxy groups in the composition constituting the ejection port forming member of preferably 90% or more, and more preferably 95% or more.

The cured product (B) preferably has a pencil hardness of 3H or more and more preferably 4H or more.

Next, as shown in FIG. 2F, an ink supply port 7 penetrating the substrate 2 is formed. The ink supply port can be formed by anisotropic etching using a resin composition having etching solution resistance as an etching mask.

Thereafter, the flow path 5 is formed by removing the mold material 11 (FIG. 2G). Further, a heat treatment is performed as needed, a member (not shown) for supplying ink is bonded and electrical bonding (not shown) for driving the energy generating elements 1 is carried out, thereby completing the ink-jet recording head.

According to the method for manufacturing an ink-jet head according to one embodiment of the present disclosure described above, it is possible to manufacture an ink-jet recording head in which ink ejection ports and ink flow paths are formed with high precision.

### EXAMPLES

The present disclosure will be specifically explained using the production examples and examples shown below. However, these do not limit the present disclosure in any way. In the production examples and examples, “parts” and “%” are all based on mass unless otherwise specified.

### Examples 1-18 and 21, Comparative Examples 1-7

### Preparation of Ink-Jet Recording Head

An explanation is given with reference to FIGS. 2A to 2G.

First, on a substrate 2 in which energy generating elements 1 were provided, polymethyl isopropenyl ketone (trade name “ODUR-1010”, manufactured by Tokyo Ohka Kogyo Co., Ltd.) as a positive photosensitive resin serving as a mold of an ink flow path was applied by spin coating, and then heat-treated at 120° C. for 6 minutes to form a positive photosensitive resin layer having a thickness of 14 μm.

Then, a pattern of the ink flow path was transferred by exposure using an exposure device UX3000 (trade name, manufactured by Ushio Inc.), the exposed portion of the positive photosensitive resin layer was developed using MIBK (methyl isobutyl ketone), and the exposed portion was then rinsed with IPA (isopropyl alcohol) to form a mold material 11 (FIG. 2A).

Next, to the mold material 11 and the substrate 2, the resin composition for an ejection port forming member shown in the respective tables was applied by spin coating, followed by a heat treatment at 60° C. for 9 minutes to form a cationically polymerizable resin layer 9 having a thickness of 25 μm (FIG. 2B).

Further, to the cationically polymerizable resin layer 9, the photosensitive resin composition for forming a water-repellent layer shown in the respective tables was applied at a film thickness of 0.5 μm, followed by a heat treatment at 90° C. for 3 minutes as a first heating step (FIG. 2C).

Next, exposure at 4000 J/m² using an i-line stepper was performed with a photomask 13 so that the diameter of a finished opening in the surface layer of the cationically polymerizable resin layer 9 was about 8.3 μm, followed by a heat treatment at 95° C. for 4 minutes as a second heating step (FIG. 2D).

Thereafter, development was performed to form an ejection port 3. The development was performed by developing with a mixed solution of MIBK and xylene, and then rinsing with xylene (FIG. 2E). A heat treatment at 140° C. for 4 minutes followed.

Then, an etching mask was formed on the back surface of the substrate 2, and the silicon substrate was subjected to anisotropic etching to form an ink supply port 7 (FIG. 2F). When doing so, a protective film (OBC manufactured by Tokyo Ohka Kogyo Co., Ltd) was applied on the photosensitive resin layer in order to protect the ejection port formation surface from the etching solution.

Next, the protective film was dissolved and removed with xylene, and then the entire surface was exposed through a negative resist at an exposure amount of 250000 mJ/cm² using a Deep-UV exposure device UX-3000 manufactured by Ushio Inc. to solubilize the mold material 11 (FIG. 2G). Subsequently, immersion in methyl lactate was carried out while applying ultrasonic waves to dissolve and remove the mold material 11 and form the flow path 5. Firing at 200° C. followed.

Thereafter, mounting processes such as bonding of a member (not shown) for supplying ink, electrical bonding (not shown) for driving the energy generating elements 1, and sealing (not shown) for protecting the electrical bonding were carried out, thereby completing the ink-jet recording head.

### Example 19

### Preparation of Ink-Jet Recording Head

In example 19, the resin composition for forming the water-repellent layer shown in Table 4 was used, and the first heating step following the application was a heat treatment at 60° C. for 3 minutes. The ink-jet recording head was prepared in the same manner as in example 1 except for the above.

### Example 20

### Preparation of Ink-Jet Recording Head

In example 20, the second heating step following the exposure was a heat treatment at 60° C. for 4 minutes. The ink-jet recording head was prepared in the same manner as in example 1 except for the above.

### Examples 1-21, Comparative Examples 1-7

### Method for Measuring the Weight Average Molecular Weight Mw of (Meth)acrylate

Analysis was performed by using HLC-8220GPC system manufactured by Tosoh Corporation as a gel permeation chromatography system, and columns “TSKgel” Super HZ2000, “TSKgel” Super HZ3000, and “TSKgel” Super HZ4000 manufactured by Tosoh Corporation connected in series. Detection was performed on a refractometer (RI) and a reference column used was one “TSKgel” Super H-RC column. A developing solvent used was tetrahydrofuran manufactured by Wako Pure Chemical Industries, Ltd., and the flow rate in the columns and the reference column was 0.35 mL/min. The measurement temperature was 40° C. for both in the plunger pump and the columns. The sample was prepared by diluting 0.025 g of each (meth)acrylate with 10 mL of tetrahydrofuran and 25 μL of the sample was injected. For the calculation of the molecular weight distribution, “TSKgel” standard polystyrenes #C, D, E and F manufactured by Tosoh Corporation were used as standard substances.

### Evaluation Method for Percentage of Reaction

### Epoxy Group

The percentage of reaction of epoxy group was calculated by using the peak area derived from the epoxy groups on the basis of the absorbance spectrum of the surface of the water-repellent layer of the ink-jet recording head obtained by Fourier transform infrared spectroscopy (FT-IR). The peak area derived from epoxy group was an integral value obtained when a line connecting the left and right minimum values that were most adjacent to the peak derived from epoxy groups around the wave number of 910 cm⁻¹ was taken as a baseline.

Specifically, the percentage E (%) of reaction of epoxy group was calculated using the following formula, wherein X was a peak area in the absorbance spectrum of the composition constituting the surface of the water-repellent layer before the exposure, and Y was a peak area in the absorbance spectrum after the exposure:

$$E ( \% ) = [ ( X - Y ) / X ] \times 100$$

### (Meth)Acrylic Group

The percentage of reaction of (meth)acrylic group was calculated by using the peak area derived from (meth)acrylic groups on the basis of the absorbance spectrum of the surface of the water-repellent layer of the ink-jet recording head obtained by FT-IR. The peak area derived from (meth)acrylic group was an integral value obtained when a line connecting the left and right minimum values that were most adjacent to the peak derived from (meth)acrylic groups around the wave number of 1500 to 1610 cm⁻¹ was taken as a baseline.

Specifically, the percentage A (%) of reaction of (meth)acrylic group was calculated using the following formula, wherein X was a peak area in the absorbance spectrum of the composition constituting the surface of the water-repellent layer before baking the coating film of the water-repellent layer, and Y was a peak area in the absorbance spectrum after the exposure:

$$A ( \% ) = [ ( X - Y ) / X ] \times 100$$

### Method for Evaluating Pencil Hardness/Water Repellency

### Pencil Hardness

The surface of the water-repellent layer of the ink-jet recording head was subjected to a pencil hardness test. Specifically, the pencil hardness was measured by testing scratching on the water-repellent layer using a pencil hardness tester specified in JIS K 5600.

### Water Repellency (Evaluation of Initial/Post-Rubbing Water Repellency)

The surface of the water-repellent layer of the ink jet recording head was evaluated for the minute contact angle. A minute contact angle analyzer (product name: DropMeasure®, manufactured by Microjet K.K.) was used. The dynamic receding contact angle θr1 of the surface of the water-repellent layer to pure water and the dynamic receding contact angle θr2 of the surface of the water-repellent layer after a rubbing test using a wiper were measured. In the rubbing test using a wiper, a pigment dispersion having a pigment concentration of 10% was dropped onto a substrate and a wiper (material: hydrogenated nitrile rubber (HNBR), rubber hardness: JIS-A hardness of 75) was rubbed against the substrate at a pressing load of 0.098 N (10 gf) therebetween back and forth 2000 times.

### Printing Evaluation of Ink-Jet Recording Head

A resin pigment dispersion ink for evaluation was placed in a tank, and printing characteristics were evaluated. The arithmetic mean value of the deviations of the landed ink from the target landing position was regarded as the landing accuracy, and the printing was evaluated according to the following criteria:
A: Landing accuracy of 3 μm or less;
B: Landing accuracy of 5 μm or less;
C: Landing accuracy of 7 μm or less;
D: Landing accuracy of above 7 μm.

### Evaluation Results

The results are shown in Tables 1 to 6. All of the examples showed excellent water repellency and pattern accuracy, and also were resulted in good printing performance. In particular, Examples 1, 3 and 4 were excellent in the print quality. Meanwhile, Comparative Examples 1 to 7 had decreased print quality.

The details of the trade names and compound names used as raw materials in the tables are given below.

### Acrylate (a)

AD-1700: “Fluorolink® PFPE AD1700” manufactured by Solvay Specialty Polymers, PFPE-urethane acrylate, Mw=3973, number of functional groups: 4
DAC-HP: “Optool® DAC-HP” manufactured by Daikin Industries, Ltd., fluorine-containing acrylate, Mw=1621, number of functional groups: 2
M-1620: “Polyflon® PTFE M-1620” manufactured by Daikin Industries, Ltd., fluorine-containing methacrylate, Mw=214, number of functional groups: 1

### Acrylate (b)

Glycidyl methacrylate: manufactured by Tokyo Chemical Industry Co., Ltd., Mw=142, number of functional groups: 1

### Acrylate (c)

UA-1100H: “NK Oligo UA-1100H” manufactured by Shin-Nakamura Chemical Co., Ltd., urethane acrylate, Mw=800, number of functional groups: 6
UA-6LPA: “NK Oligo U-6LPA” manufactured by Shin-Nakamura Chemical Co., Ltd., urethane acrylate, Mw-850, number of functional groups: 6
EBECRYL 3603: “EBECRYL® 3603” manufactured by Daicel-Allnex Ltd., novolac epoxy acrylate, Mw=760, number of functional groups: 3
UA-16HA: “NK Oligo UA-16HA” manufactured by Shin-Nakamura Chemical Co., Ltd., urethane acrylate, Mw=2300, number of functional groups: 6
Miramer PE210: “Miramer PE210” manufactured by Toyo Chemicals Co., Ltd., Mw-620, number of functional groups: 2
UV-7605B: “SHIKOH® UV-7605B” manufactured by Mitsubishi Chemical Corporation, urethane acrylate, Mw=11000, number of functional groups: 6

### Thermal Radical Polymerization Initiator (d)

V-65: “V-65” manufactured by FUJIFILM Wako Pure Chemical Corp., azo-based polymerization initiator, 10-hour half-life temperature=65° C.
V-086: “V-086” manufactured by FUJIFILM Wako Pure Chemical Corp., azo-based polymerization initiator, 10-hour half-life temperature=86° C.

### Photo Cationic Polymerization Initiator (e)

SP-172: “ADEKA ARKLS SP-172” manufactured by ADEKA Corporation, photo cationic polymerization initiator, anionic structure-hexafluoroantimonate, molar extinction coefficient=1.6 L/(mol·cm)
CPI-110A: “CPI®-110A” manufactured by San-Apro Ltd., photo cationic polymerization initiator, anionic structure-hexafluoroantimonate, molar extinction coefficient=0.16 L/(mol·cm)
TPS-1000: “TPS-1000” manufactured by Midori Kagaku Co., Ltd., photo cationic polymerization initiator, anionic structure=trifluoromethanesulfonate, molar extinction coefficient-0 L/(mol·cm)

### Epoxy Resin

EHPE-3150: “EHPE3150” manufactured by Daicel Corporation, alicyclic epoxy resin
jER 157S70: “jER® 157S70” manufactured by Mitsubishi Chemical Corporation, phenol novolac epoxy resin

### Solvent

MIBK: “4-Methyl-2-pentanone” manufactured by Kishida Chemical Co., Ltd.
OMR thinner: “OMR thinner” manufactured by Tokyo Ohka Kogyo Co., Ltd.

TABLE 1

| | | | | Example 1 | Example 2 | Example 3 | Example 4 | Example 5 |
|---|---|---|---|---|---|---|---|---|
| Water- | Raw | Acrylate (a) | Trade name or | AD-1700 | AD-1700 | AD-1700 | AD-1700 | AD-1700 |
| repellent | materials | | compound name | | | | | |
| layer | | | Parts by mass | 5 | 5 | 5 | 47.5 | 5 |
| | | Acrylate (b) | Trade name or | Glycidyl | Glycidyl | Glycidyl | Glycidyl | Glycidyl |
| | | | compound name | methacrylate | methacrylate | methacrylate | methacrylate | methacrylate |
| | | | Parts by mass | 47.5 | 47.5 | 47.5 | 47.5 | 47.5 |
| | | Acrylate (c) | Trade name or | UA-1100H | UA-1100H | UA-6LPA | UA-1100H | EBECRYL 3603 |
| | | | compound name | | | | | |
| | | | Parts by mass | 47.5 | 47.5 | 47.5 | 5 | 47.5 |
| | | Thermal radical | Trade name or | V-65 | V-65 | V-65 | V-65 | V-65 |
| | | polymerization | compound name | | | | | |
| | | initiator (d) | Parts by mass | 0.5 | 0.5 | 0.5 | 0.5 | 0.5 |
| | | Photo cationic | Trade name or | SP-172 | SP-172 | SP-172 | SP-172 | SP-172 |
| | | polymerization | compound name | | | | | |
| | | initiator (e) | Parts by mass | 0.5 | 0.5 | 0.5 | 0.5 | 0.5 |
| | | Solvent | Trade name or | MIBK | MIBK | MIBK | MIBK | MIBK |
| | | | compound name | | | | | |
| | | | Parts by mass | 50 | 50 | 50 | 50 | 50 |
| Ejection | Raw | Epoxy resin | Trade name or | EHPE-3150 | jER157S70 | EHPE-3150 | EHPE-3150 | EHPE-3150 |
| port | materials | | compound name | | | | | |
| forming | | | Parts by mass | 100 | 100 | 100 | 100 | 100 |
| member | | Photo cationic | Trade name or | SP-172 | SP-172 | SP-172 | SP-172 | SP-172 |
| | | polymerization | compound name | | | | | |
| | | initiator | Parts by mass | 3 | 3 | 3 | 3 | 3 |
| | | Solvent | Trade name or | OMR thinner | OMR thinner | OMR thinner | OMR thinner | OMR thinner |
| | | | compound name | | | | | |
| | | | Parts by mass | 50 | 50 | 50 | 50 | 50 |

| Evaluation | Percentage of | Epoxy group | 95 | 90 | 95 | 95 | 90 |
|---|---|---|---|---|---|---|---|
| | reaction (%) | (Meth)acrylic group | 95 | 95 | 95 | 95 | 95 |
| | Pencil hardness | Water-repellent layer | 4H | 3H | 4H | 4H | 3H |

| | | | | | |
|---|---|---|---|---|---|
| Initial dynamic receding contact angle θr1 (°) | 95 | 92 | 95 | 95 | 92 |
| Post-rubbing test dynamic receding contact | 85 | 83 | 85 | 85 | 83 |
| angle θr2 (°) | | | | | |
| Initial contact angle − post-rubbing contact | 10 | 9 | 10 | 10 | 9 |
| angle (°) | | | | | |
| Print evaluation | A | A | A | A | A |

TABLE 2

| | | | | Example 6 | Example 7 | Example 8 | Example 9 | Example 10 |
|---|---|---|---|---|---|---|---|---|
| Water- | Raw | Acrylate (a) | Trade name or | AD-1700 | AD-1700 | AD-1700 | AD-1700 | AD-1700 |
| repellent | materials | | compound name | | | | | |
| layer | | | Parts by mass | 5 | 5 | 5 | 5 | 5 |
| | | Acrylate (b) | Trade name or | Glycidyl | Glycidyl | Glycidyl | Glycidyl | Glycidyl |
| | | | compound name | methacrylate | methacrylate | methacrylate | methacrylate | methacrylate |
| | | | Parts by mass | 47.5 | 47.5 | 47.5 | 47.5 | 47.5 |
| | | Acrylate (c) | Trade name or | UA-1100H | UA-1100H | UA-6LPA | UA-1100H | UA-1100H |
| | | | compound name | | | | | |
| | | | Parts by mass | 47.5 | 47.5 | 47.5 | 47.5 | 47.5 |
| | | Thermal radical | Trade name or | V-65 | V-65 | V-086 | V-65 | V-65 |
| | | polymerization | compound name | | | | | |
| | | initiator (d) | Parts by mass | 0.01 | 20 | 0.5 | 0.5 | 0.5 |
| | | Photo cationic | Trade name or | SP-172 | SP-172 | SP-172 | SP-172 | CPI-110A |
| | | polymerization | compound name | | | | | |
| | | initiator (e) | Parts by mass | 0.5 | 0.5 | 0.5 | 0.001 | 0.5 |
| | | Solvent | Trade name or | MIBK | MIBK | MIBK | MIBK | MIBK |
| | | | compound name | | | | | |
| | | | Parts by mass | 50 | 50 | 50 | 50 | 50 |
| Ejection | Raw | Epoxy resin | Trade name or | EHPE-3150 | EHPE-3150 | EHPE-3150 | EHPE-3150 | EHPE-3150 |
| port | materials | | compound name | | | | | |
| forming | | | Parts by mass | 100 | 100 | 100 | 100 | 100 |
| member | | Photo cationic | Trade name or | SP-172 | SP-172 | SP-172 | SP-172 | SP-172 |
| | | polymerization | compound name | | | | | |
| | | initiator | Parts by mass | 3 | 3 | 3 | 3 | 3 |
| | | Solvent | Trade name or | OMR thinner | OMR thinner | OMR thinner | OMR thinner | OMR thinner |
| | | | compound name | | | | | |
| | | | Parts by mass | 50 | 50 | 50 | 50 | 50 |

| Evaluation | Percentage of | Epoxy group | 95 | 85 | 95 | 80 | 85 |
|---|---|---|---|---|---|---|---|
| | reaction (%) | (Meth)acrylic group | 80 | 90 | 95 | 95 | 95 |
| | Pencil hardness | Water-repellent layer | 2H | 2H | 4H | 2H | 3H |

| | | | | | |
|---|---|---|---|---|---|
| Initial dynamic receding contact angle θr1 (°) | 88 | 88 | 95 | 90 | 88 |
| Post-rubbing test dynamic receding contact | 75 | 75 | 85 | 83 | 75 |
| angle θr2 (°) | | | | | |
| Initial contact angle − post-rubbing contact | 13 | 13 | 10 | 7 | 13 |
| angle (°) | | | | | |
| Print evaluation | B | B | A | A | B |

TABLE 3

| | | | | Example 11 | Example 12 | Example 13 | Example 14 | Example 15 |
|---|---|---|---|---|---|---|---|---|
| Water- | Raw | Acrylate (a) | Trade name or | AD-1700 | AD-1700 | AD-1700 | AD-1700 | AD-1700 |
| repellent | materials | | compound name | | | | | |
| layer | | | Parts by mass | 5 | 5 | 0.5 | 300 | 47.5 |
| | | Acrylate (b) | Trade name or | Glycidyl | Glycidyl | Glycidyl | Glycidyl | Glycidyl |
| | | | compound name | methacrylate | methacrylate | methacrylate | methacrylate | methacrylate |
| | | | Parts by mass | 47.5 | 47.5 | 47.5 | 47.5 | 4 |
| | | Acrylate (c) | Trade name or | UA-1100H | UA-1100H | UA-1100H | UA-1100H | UA-1100H |
| | | | compound name | | | | | |
| | | | Parts by mass | 47.5 | 47.5 | 47.5 | 47.5 | 47.5 |
| | | Thermal radical | Trade name or | V-65 | V-65 | V-65 | V-65 | V-65 |
| | | polymerization | compound name | | | | | |
| | | initiator (d) | Parts by mass | 0.5 | 0.5 | 0.5 | 0.5 | 0.5 |
| | | Photo cationic | Trade name or | TPS-1000 | SP-172 | SP-172 | SP-172 | SP-172 |
| | | polymerization | compound name | | | | | |
| | | initiator (e) | Parts by mass | 0.5 | 10 | 0.5 | 0.5 | 0.5 |
| | | Solvent | Trade name or | MIBK | MIBK | MIBK | MIBK | MIBK |
| | | | compound name | | | | | |
| | | | Parts by mass | 50 | 50 | 50 | 50 | 50 |
| Ejection | Raw | Epoxy resin | Trade name or | EHPE-3150 | EHPE-3150 | EHPE-3150 | EHPE-3150 | EHPE-3150 |
| port | materials | | compound name | | | | | |
| forming | | | Parts by mass | 100 | 100 | 100 | 100 | 100 |
| member | | Photo cationic | Trade name or | SP-172 | SP-172 | SP-172 | SP-172 | SP-172 |
| | | polymerization | compound name | | | | | |
| | | initiator | Parts by mass | 3 | 3 | 3 | 3 | 3 |
| | | Solvent | Trade name or | OMR thinner | OMR thinner | OMR thinner | OMR thinner | OMR thinner |
| | | | compound name | | | | | |
| | | | Parts by mass | 50 | 50 | 50 | 50 | 50 |

| Evaluation | Percentage of | Epoxy group | 80 | 95 | 95 | 90 | 95 |
|---|---|---|---|---|---|---|---|
| | reaction (%) | (Meth)acrylic group | 95 | 95 | 90 | 90 | 95 |
| | Pencil hardness | Water-repellent layer | 2H | 2H | 2H | 2H | 2H |

| | | | | | |
|---|---|---|---|---|---|
| Initial dynamic receding contact angle θr1 | 90 | 95 | 80 | 90 | 91 |
| (°) | | | | | |
| Post-rubbing test dynamic receding contact | 82 | 80 | 65 | 70 | 80 |
| angle θr2 (°) | | | | | |
| Initial contact angle − post-rubbing contact | 8 | 15 | 15 | 20 | 11 |
| angle (°) | | | | | |
| Print evaluation | A | B | B | C | B |

TABLE 4

| | | | | Example 16 | Example 17 | Example 18 | Example 19 | Example 20 | Example 21 |
|---|---|---|---|---|---|---|---|---|---|
| Water- | Raw | Acrylate (a) | Trade name or | AD-1700 | AD-1700 | AD-1700 | AD-1700 | AD-1700 | AD-1700 |
| repellent | materials | | compound name | | | | | | |
| layer | | | Parts by mass | 5 | 47.5 | 5 | 5 | 5 | 5 |
| | | Acrylate (b) | Trade name or | Glycidyl | Glycidyl | Glycidyl | Glycidyl | Glycidyl | Glycidyl |
| | | | compound name | methacrylate | methacrylate | methacrylate | methacrylate | methacrylate | methacrylate |
| | | | Parts by mass | 95 | 47.5 | 5 | 47.5 | 47.5 | 47.5 |
| | | Acrylate (c) | Trade name or | UA-1100H | UA-1100H | UA-1100H | UA-1100H | UA-1100H | UA-15HA |
| | | | compound name | | | | | | |
| | | | Parts by mass | 5 | 1 | 47.5 | 47.5 | 47.5 | 47.5 |
| | | Thermal radical | Trade name or | V-65 | V-65 | V-65 | V-65 | V-65 | V-65 |
| | | polymerization | compound name | | | | | | |
| | | initiator (d) | Parts by mass | 0.5 | 0.5 | 0.5 | 0.5 | 0.5 | 0.5 |
| | | Photo cationic | Trade name or | SP-172 | SP-172 | SP-172 | SP-172 | SP-172 | SP-172 |
| | | polymerization | compound name | | | | | | |
| | | initiator (e) | Parts by mass | 0.5 | 0.5 | 0.5 | 0.5 | 0.5 | 0.5 |
| | | Solvent | Trade name or | MIBK | MIBK | MIBK | MIBK | MIBK | MIBK |
| | | | compound name | | | | | | |
| | | | Parts by mass | 50 | 50 | 50 | 50 | 50 | 50 |
| Ejection | Raw | Epoxy resin | Trade name or | EHPE-3150 | EHPE-3150 | EHPE-3150 | EHPE-3150 | EHPE-3150 | EHPE-3150 |
| port | materials | | compound name | | | | | | |
| forming | | | Parts by mass | 100 | 100 | 100 | 100 | 100 | 100 |
| member | | Photo cationic | Trade name or | SP-172 | SP-172 | SP-172 | SP-172 | SP-172 | SP-172 |
| | | polymerization | compound name | | | | | | |
| | | initiator | Parts by mass | 3 | 3 | 3 | 3 | 3 | 3 |
| | | Solvent | Trade name or | OMR thinner | OMR thinner | OMR thinner | OMR thinner | OMR thinner | OMR thinner |
| | | | compound name | | | | | | |
| | | | Parts by mass | 50 | 50 | 50 | 50 | 50 | 50 |

| Evaluation | Percentage of | Epoxy group | 90 | 90 | 90 | 95 | 95 | 95 |
|---|---|---|---|---|---|---|---|---|
| | reaction (%) | (Meth)acrylic group | 95 | 90 | 90 | 80 | 80 | 95 |
| | Pencil hardness | Water-repellent layer | 3H | 2H | 4H | 2H | 2H | 6H |

| | | | | | | |
|---|---|---|---|---|---|---|
| Initial dynamic receding contact angle | 90 | 88 | 85 | 88 | 88 | 95 |
| θr1 (°) | | | | | | |
| Post-rubbing test dynamic receding | 80 | 75 | 70 | 73 | 73 | 85 |
| contact angle θr2 (°) | | | | | | |
| Initial contact angle − post-rubbing | 10 | 13 | 15 | 15 | 15 | 10 |
| contact angle (°) | | | | | | |
| Print evaluation | A | B | B | B | B | A |

TABLE 5

| | | | | Comparative | Comparative | Comparative | Comparative | Comparative |
|---|---|---|---|---|---|---|---|---|
| | | | | Example 1 | Example 2 | Example 3 | Example 4 | Example 5 |
| Water- | Raw | Acrylate (a) | Trade name or | DAC-HP | M-1620 | AD-1700 | AD-1700 | AD-1700 |
| repellent | materials | | compound name | | | | | |
| layer | | | Parts by mass | 5 | 5 | 5 | 5 | 5 |
| | | Acrylate (b) | Trade name or | Glycidyl | Glycidyl | Glycidyl | Glycidyl | Glycidyl |
| | | | compound name | methacrylate | methacrylate | methacrylate | methacrylate | methacrylate |
| | | | Parts by mass | 47.5 | 47.5 | 47.5 | 47.5 | 47.5 |
| | | Acrylate (c) | Trade name or | UA-1100H | UA-1100H | — | MiramerPE210 | UV-7605B |
| | | | compound name | | | | | |
| | | | Parts by mass | 47.5 | 47.5 | — | 47.5 | 47.5 |
| | | Thermal radical | Trade name or | V-65 | V-65 | V-65 | V-65 | V-65 |
| | | polymerization | compound name | | | | | |
| | | initiator (d) | Parts by mass | 0.5 | 0.5 | 0.5 | 0.5 | 0.5 |
| | | Photo cationic | Trade name or | SP-172 | SP-172 | SP-172 | SP-172 | SP-172 |
| | | polymerization | compound name | | | | | |
| | | initiator (e) | Parts by mass | 0.5 | 0.5 | 0.5 | 0.5 | 0.5 |
| | | Solvent | Trade name or | MIBK | MIBK | MIBK | MIBK | MIBK |
| | | | compound name | | | | | |
| | | | Parts by mass | 50 | 50 | 50 | 50 | 50 |
| Ejection | Raw | Epoxy resin | Trade name or | EHPE-3150 | jER157S70 | EHPE-3150 | EHPE-3150 | EHPE-3150 |
| port | materials | | compound name | | | | | |
| forming | | | Parts by mass | 100 | 100 | 100 | 100 | 100 |
| member | | Photo cationic | Trade name or | SP-172 | SP-172 | SP-172 | SP-172 | SP-172 |
| | | polymerization | compound name | | | | | |
| | | initiator | Parts by mass | 3 | 3 | 3 | 3 | 3 |
| | | Solvent | Trade name or | OMR thinner | OMR thinner | OMR thinner | OMR thinner | OMR thinner |
| | | | compound name | | | | | |
| | | | Parts by mass | 50 | 50 | 50 | 50 | 50 |

| Evaluation | Percentage of | Epoxy group | 90 | 90 | 80 | 90 | 90 |
|---|---|---|---|---|---|---|---|
| | reaction (%) | (Meth)acrylic group | 90 | 90 | 70 | 75 | 75 |
| | Pencil hardness | Water-repellent layer | 3H | 3H | HB | HB | HB |

| | | | | | |
|---|---|---|---|---|---|
| Initial dynamic receding contact angle θr1 | 75 | 73 | 75 | 74 | 72 |
| (°) | | | | | |
| Post-rubbing test dynamic receding contact | 60 | 60 | 60 | 61 | 58 |
| angle θr2 (°) | | | | | |
| Initial contact angle − post-rubbing contact | 15 | 13 | 15 | 13 | 14 |
| angle (°) | | | | | |
| Print evaluation | D | D | D | D | D |

TABLE 6

| | | | | Comparative | Comparative |
|---|---|---|---|---|---|
| | | | | Example 6 | Example 7 |
| Water- | Raw | Acrylate (a) | Trade name or | AD-1700 | AD-1700 |
| repellent | materials | | compound name | | |
| layer | | | Parts by mass | 5 | 5 |
| | | Acrylate (b) | Trade name or | Glycidyl | Glycidyl |
| | | | compound name | methacrylate | methacrylate |
| | | | Parts by mass | 47.5 | 47.5 |
| | | Acrylate (c) | Trade name or | UA-1100H | UA-1100H |
| | | | compound name | | |
| | | | Parts by mass | 47.5 | 47.5 |
| | | Thermal radical | Trade name or | — | V-65 |
| | | polymerization initiator (d) | compound name | | |
| | | | Parts by mass | — | 0.5 |
| | | Photo cationic | Trade name or | SP-172 | — |
| | | polymerization initiator (e) | compound name | | |
| | | | Parts by mass | 0.5 | — |
| | | Solvent | Trade name or | MIBK | MIBK |
| | | | compound name | | |
| | | | Parts by mass | 50 | 50 |
| Ejection port | Raw | Epoxy resin | Trade name or | EHPE-3150 | EHPE-3150 |
| forming | materials | | compound name | | |
| member | | | Parts by mass | 100 | 100 |
| | | Photo cationic | Trade name or | SP-172 | SP-172 |
| | | polymerization initiator | compound name | | |
| | | | Parts by mass | 3 | 3 |
| | | Solvent | Trade name or | OMR thinner | OMR thinner |
| | | | compound name | | |
| | | | Parts by mass | 50 | 50 |

| Evaluation | Percentage of reaction | Epoxy group | 85 | 70 |
|---|---|---|---|---|
| | (%) | (Meth)acrylic group | 60 | 90 |
| | Pencil hardness | Water-repellent layer | HB | HB |

| | | |
|---|---|---|
| Initial dynamic receding contact angle θr1 (°) | 70 | 70 |
| Post-rubbing test dynamic receding contact angle | 56 | 55 |
| θr2 (°) | | |
| Initial contact angle − post-rubbing contact | 14 | 15 |
| | angle (°) | |
| Print evaluation | D | D |

One embodiment of the present disclosure provides an ink-jet recording head having high water repellency and durability.

Another embodiment of the present disclosure provides a method for manufacturing an ink-jet recording head having high water repellency and durability.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-220982, filed Dec. 17, 2024, which is hereby incorporated by reference herein in its entirety.

What is claimed is:

1. An ink-jet recording head comprising:
a substrate;
an ejection port forming member provided on the substrate; and
a water-repellent layer provided on the ejection port forming member, wherein
the water-repellent layer comprises a cured product (A) of a photosensitive resin composition,
the photosensitive resin composition comprises:
a (meth)acrylate (a) having a perfluoropolyether group;
a (meth)acrylate (b) having an epoxy group;
a multifunctional (meth)acrylate (c);
a thermal radical polymerization initiator (d); and
a photo cationic polymerization initiator (e),
the (meth)acrylate (a) is a (meth)acrylate having a tri- or more functional (meth)acrylic group, and
the multifunctional (meth)acrylate (c) is a (meth)acrylate having a weight average molecular weight of not more than 5000 and having a hexa- or more functional (meth)acrylic group.

2. The ink-jet recording head according to claim 1, wherein the (meth)acrylate (a) has a weight average molecular weight of not more than 5000.

3. The ink-jet recording head according to claim 1, wherein the (meth)acrylate (a) has (meth)acrylate structures at both termini.

4. The ink-jet recording head according to claim 1, wherein the (meth)acrylate (a) has a urethane bond.

5. The ink-jet recording head according to claim 1, wherein the (meth)acrylate (a) is a compound represented by formula (1): 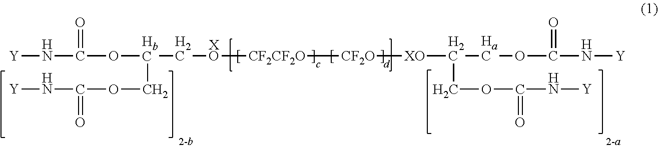
in formula (1), a and b are each independently an integer of 0 to 2; c is an average number of repetitions of the repeating unit —(CF₂CF₂O)—, d is an average number of repetitions of the repeating unit —(CF₂O)—, c and d each independently represent a number of at least 0 and satisfy 15≤(c+d)≤25; in a case of having both repeating units, these repeating units may be linked via any of block bonds, random bonds, and block bonds and random bonds; Y groups each independently represent a group represented by formula (Y1) or (Y2) below; and X groups each independently represent an alkylene group having 2 or 3 carbon atoms substituted with 1 to 3 fluorine atoms; 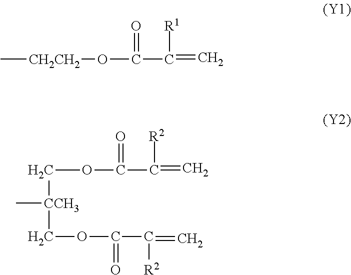
in formulae (Y1) and (Y2), R¹ and R² each independently represent a hydrogen atom or a methyl group.

6. The ink-jet recording head according to claim 1, wherein the (meth)acrylate (a) is soluble in an organic solvent.

7. The ink-jet recording head according to claim 6, wherein the organic solvent is a ketone solvent.

8. The ink-jet recording head according to claim 1, wherein a content of the (meth)acrylate (a) in the photosensitive resin composition is 1 to 60% by mass, provided that a total content of all (meth)acrylates in the photosensitive resin composition is 100% by mass.

9. The ink-jet recording head according to claim 1, wherein the epoxy group of the (meth)acrylate (b) is alicyclic or glycidyl.

10. The ink-jet recording head according to claim 1, wherein a content of the (meth)acrylate (b) in the photosensitive resin composition is 10 to 90% by mass, provided that a total content of all (meth)acrylates in the photosensitive resin composition is 100% by mass.

11. The ink-jet recording head according to claim 1, wherein the thermal radical polymerization initiator (d) has a 10-hour half-life temperature of not higher than 80° C.

12. The ink-jet recording head according to claim 1, wherein a content of the thermal radical polymerization initiator (d) is 0.5 to 10% by mass, provided that a total content of all (meth)acrylates in the photosensitive resin composition is 100% by mass.

13. The ink-jet recording head according to claim 1, wherein a cation of the photo cationic polymerization initiator (e) is a sulfonium ion.

14. The ink-jet recording head according to claim 1, wherein the photo cationic polymerization initiator (e) has a molar extinction coefficient of at least 0.3 L/(mol·cm) at a wavelength of 365 nm.

15. The ink-jet recording head according to claim 1, wherein an anion of the photo cationic polymerization initiator (e) is at least one anion selected from the group consisting of tetrakis(pentafluorophenyl)gallate and hexafluoroantimonate.

16. The ink-jet recording head according to claim 1, wherein a content of the photo cationic polymerization initiator (e) in the photosensitive resin composition is 0.00001 to 0.15 times the mass of the (meth)acrylate (b).

17. The ink-jet recording head according to claim 1, wherein the ejection port forming member is a cured product (B) of a composition containing an epoxy resin and a photo cationic polymerization initiator, and wherein the epoxy resin is an alicyclic or glycidyl epoxy resin.

18. The ink-jet recording head according to claim 1, wherein in the cured product (A), a total percentage of reaction of (meth)acrylic group based on a total of all (meth)acrylic groups of the (meth)acrylates (a) to (c) is at least 90%.

19. The ink-jet recording head according to claim 1, wherein in the cured product (A), a total percentage of reaction of epoxy group based on a total of epoxy groups in the photosensitive resin composition is 90% or more.

20. A method for manufacturing an ink-jet recording head, the ink-jet recording head including:
a substrate; and
an ejection port forming member provided on the substrate, wherein
the method comprises a step of forming a water-repellent layer on the ejection port forming member,
a resin composition forming the water-repellent layer comprises:
a (meth)acrylate (a) having a perfluoropolyether group;
a (meth)acrylate (b) having an epoxy group;
a multifunctional (meth)acrylate (c);
a thermal radical polymerization initiator (d); and
a photo cationic polymerization initiator (e),
the (meth)acrylate (a) is a (meth)acrylate having a tri- or more functional (meth)acrylic group, and
the multifunctional (meth)acrylate (c) comprises a (meth)acrylate having a weight average molecular weight of not more than 5000 and having a hexa- or more functional (meth)acrylic group.
